(19) United States
(12) Patent Application Publication
(10) Pub. No.: US 2014/0145173 A1
(43) Pub. Date: May 29, 2014

(54) WHITE LIGHT EMITTING ORGANIC ELECTROLUMINESCENT DEVICE AND ORGANIC ELECTROLUMINESCENT DISPLAY HAVING THE SAME

(71) Applicant: Samsung Display Co., Ltd., Yongin-city (KR)

(72) Inventors: Byung-Doo CHIN, Seongnam-si (KR); Mu-Hyun KIM, Suwon-si (KR); Seong-Taek LEE, Suwon-si (KR); Nam-Choul YANG, Seoul (KR); Min-Chul SUH, Seongnam-si (KR); Jang-Hyuk KWON, Suwon-si (KR)

(73) Assignee: Samsung Display Co., Ltd., Yongin-city (KR)

(21) Appl. No.: 14/166,655

(22) Filed: Jan. 28, 2014

Related U.S. Application Data
(63) Continuation of application No. 11/019,461, filed on Dec. 23, 2004.

(30) Foreign Application Priority Data
Jan. 13, 2004 (KR) 10-2004-0002454

(51) Int. Cl. H01L 51/50

(52) U.S. Cl. CPC H01L 51/504
USPC 257/40

(57) ABSTRACT

A white light emitting organic electroluminescent device and organic electroluminescent display having the same are provided. The organic electroluminescent device includes a first electrode, a second electrode, and an emission layer interposed between the first and second electrodes and having a fluorescence layer and a phosphorescence layer. Thereby, it is possible to obtain the white light emitting organic electroluminescent device having luminance yield improved.

### CROSS-REFERENCE TO RELATED APPLICATIONS

This application is a continuation of U.S. patent application Ser. No. 11/019,461, filed on Dec. 23, 2004, and claims priority to and the benefit of Korean Patent Application No. 10-2004-0002454, filed on Jan. 13, 2004, which are all hereby incorporated by reference for all purposes as if fully set forth herein.

### BACKGROUND OF THE INVENTION

1. Field of the Invention

The present invention relates to an organic electroluminescent device and, more particularly, to an organic electroluminescent device emitting white light.

2. Description of the Related Art

An organic electroluminescent device emitting white light has a variety of applications for a paper thin light source, a backlight of a liquid crystal display, a full color display employing a color filter, and so forth.

This white light emitting organic electroluminescent device has been disclosed in U.S. Pat. No. 6,627,333. According to U.S. Pat. No. 6,627,333, the organic electroluminescent device is composed of a first electrode, a hole injection layer, a hole transport layer, an emission layer, an electron transport layer, an electron injection layer, and a second electrode. The emission layer is doped with a compound emitting blue fluorescent light, and the hole transport layer and/or the electron transport layer which come(s) into contact with the emission layer are/is doped with a compound emitting yellow fluorescent light. However, according to U.S. Pat. No. 6,627,333, the organic electroluminescent device shows a low luminance yield of 3 to 5 cd/A or so.

### SUMMARY OF THE INVENTION

The present invention, therefore, solves aforementioned problems associated with the conventional art by providing an organic electroluminescent device having luminance yield improved.

In an exemplary embodiment according to the present invention, an organic electroluminescent device emitting white light includes a first electrode, a second electrode, and an emission layer interposed between the first and second electrodes and having a fluorescence layer and a phosphorescence layer.

In another exemplary embodiment according to the present invention, an organic electroluminescent display includes: first and second electrodes, at least one of which is a transparent electrode; an emission layer interposed between the first and second electrodes and having a fluorescence layer and a phosphorescence layer to emit white light on driving; and a color filter layer located on a path through which light extracted outside from the emission layer passes.

In the organic electroluminescent device or the organic electroluminescent display, the fluorescence layer, preferably, is the emission layer emitting light in the blue range. In this case, the fluorescence layer may include one selected from a group consisting of distyrylarylene (DSA), a DSA derivative, distyrylbenzene (DSB), a DSB derivative, 4,4′-bis(2,2′-diphenyl vinyl)-1,1′-biphenyl (DPVBi), a DPVBi derivative, spiro-DPVBi, spiro-sexyphenyl (spiro-6P), 9,10-bis[(2′7″-t-butyl)-9′,9″-spirobifluorenyl]anthracene (TBSA), 2,5-bis{4-[bis-(9,9-dimethyl-2-fluorenyl)amino]phenyl}thiophene (BFA-1T), and N-arylbenzimidazoles (TPBI). In addition, preferably, the fluorescence layer further includes one dopant material selected from a group consisting of a styrylamine, a phenylene, and a distyrylbiphenyl.

In the organic electroluminescent device or the organic electroluminescent display, the phosphorescence layer may be the emission layer emitting light in the orange-red range. In this case, the phosphorescence layer may include one, as a host material, selected from a group consisting of an arylamine, a carbazole, and a spiro. The host material may include one selected from a group consisting of 4,4-N,N dicarbazole-biphenyl (CBP), a CBP derivative, N,N-dicarbazolyl-3,5-benzene (mCP) and a mCP derivative. The phosphorescence layer may include a phosphorescent organic metal complex having one central metal selected from a group consisting of Ir, Pt, Tb and Eu, as a dopant material. The dopant material may include one phosphorescent organic metal complex selected from a group consisting of PQIr(acac), PQ₂Ir(acac) (iridium(III)bis(2-phenylquinolyl-N,C2′)acetylacetonate), PIQIr(acac), PtOEP (2,3,7,8,12,13,17,18-octaethyl-21H,23H-porphine platinum), bis(2-(2′-benzo[4,5-a]thienyl)pyridinato-N,C2′)iridium(acetylacetonate) (Btp₂Ir), and Tris[1-phenylisoquinolinato-C2,N]iridium(III) (Ir(piq)₃).

Most preferably, the fluorescence layer is the emission layer emitting light in the blue range, and the phosphorescence layer is the emission layer emitting light in the orange-red range.

The organic electroluminescent device or the organic electroluminescent display may further include at least one selected from a group consisting of a hole injection layer, a hole transport layer, an electron injection layer, an electron transport layer and a hole blocking layer.

In the organic electroluminescent device or the organic electroluminescent display, the first electrode may be an anode, the fluorescence layer may be located on the first electrode, and the phosphorescence layer may be located on the fluorescence layer. In this case, the organic electroluminescent device may further include a hole blocking layer located on the phosphorescence layer. At this time, the fluorescence layer, preferably, has a thickness of 50 to 200 Å, and the phosphorescence layer, preferably, has a thickness of 50 to 300 Å.

Alternatively, the first electrode may be an anode, the phosphorescence layer may be located on the first electrode, and the fluorescence layer may be located on the phosphorescence layer. At this time, the phosphorescence layer, preferably, has a thickness of 50 to 200 Å, and the fluorescence layer, preferably, has a thickness of 50 to 300 Å.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross-sectional view for illustrating an organic electroluminescent device and method of fabricating the same in accordance with a first embodiment of the present invention;

FIG. 2 is a cross-sectional view for illustrating an organic electroluminescent device and method of fabricating the same in accordance with a second embodiment of the present invention; and

FIG. 3 is a cross-sectional view showing a full-color organic electroluminescent display and method of fabricating the same in accordance with a third embodiment of the present invention.

### DETAILED DESCRIPTION OF THE INVENTION

Hereinafter, the present invention will now be described in more detail with reference to the accompanying drawings, in which exemplary embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those ordinarily skilled in the art. In the drawings, like numbers refer to like elements throughout the specification.

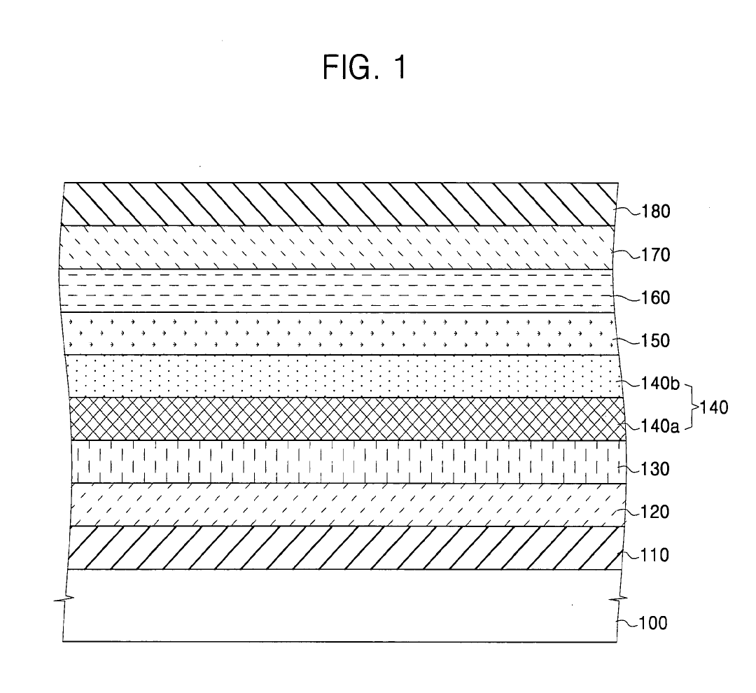

FIG. 1 is a cross-sectional view for explaining an organic electroluminescent device and a method of fabricating the same in accordance with a first embodiment of the present invention.

Referring to FIG. 1, a first electrode 110 is formed on a substrate 100. The first electrode 110 may be formed of a transparent electrode or a reflective electrode. When the first electrode 110 is formed of the transparent electrode, it is formed of ITO (indium tin oxide) or IZO (indium zinc oxide). When the first electrode 110 is formed of the reflective electrode, it is formed of Ag, Al, Mi, Pt, Pd, or their alloys. Thereby, the first electrode 110 may be formed as an anode.

A hole injection layer (HIL) 120 as an electric charge injection layer, and a hole transport layer (HTL) 130 as an electric charge transport layer may be sequentially formed on the first electrode 110. Alternatively, any one of the hole injection layer 120 and the hole transport layer 130 may not be formed. The hole injection layer 120 is a layer for facilitating to inject holes into an emission layer which will be formed in the subsequent process, which may be formed of a low molecular weight material such as CuPc, TNATA, TCTA, TDAPB or TDATA, or a polymer material (high molecular material) such as PANI or PEDOT. Further, the hole transport layer 130 is a layer for facilitating to transport holes to an emission layer which will be formed in the subsequent process, which may be formed of a low molecular weight material such as α-NPB, TPD, s-TAD or MTADATA, or a polymer material such as PVK.

A fluorescence layer 140a is formed on the hole transport layer 130. The fluorescence layer 140a is preferably formed of an emission layer that emits light belonging to a blue range. The blue light may have a wavelength of 440 to 500 nm. In this case, the fluorescence layer 140a may be formed to contain one selected from a group consisting of DSA (distyrylarylene), a DSA derivative, DSB (distyrylbenzene), a DSB derivative, DPVBi (4,4′-bis(2,2′-diphenyl vinyl)-1,1′-biphenyl), a DPVBi derivative, spiro-DPVBi, spiro-sexyphenyl(spiro-6P), 9,10-bis[(2″7″-t-butyl)-9′,9″-spirobifluorenyl]anthracene (TBSA), 2,5-bis{4-[bis-(9,9-dimethyl-2-fluorenyl)amino]phenyl}thiophene (BFA-1T), and N-arylbenzimidazole (TPBI). Furthermore, the fluorescence layer 140a may be formed to further contain one selected from a group consisting of a styrylamine, a phenylene, and a DSBP (distyrylbiphenyl), as a dopant material.

A phosphorescence layer 140b is formed on the fluorescence layer 140a. The phosphorescence layer 140b is preferably formed of an emission layer that emits light belonging to an orange-red range. The orange-red light may have a wavelength of 560 to 620 nm. In this case, the phosphorescence layer 140b may contain one selected from a group consisting of an arylamine, a carbazole, and a spiro group. The host material may include on selected from a group consisting of 4,4-N,N dicarbazole-byphenyl (CBP), a (CBP) derivative, N,N-dicarbazolyl-3,5-benzene (mCP), and an mCP derivative. In addition, the phosphorescence layer 140b may include a phosphorescent organic metal complex having one central metal selected from a group consisting of Ir, Pt, Tb, and Eu, as a dopant material. The dopant material may contain one, as a phosphorescent organic metal complex, selected from a group consisting of PQIr(acac), PQ₂Ir (acac), PIQIr(acac), PtOEP, Btp₂Ir, and Ir(piq)₃.

Most preferably, the fluorescence layer 140a is formed as an emission layer emitting blue light, and the phosphorescence layer 140b in formed as an emission layer emitting orange-red light. Alternatively, the fluorescence layer 140a may be formed as an emission layer emitting orange-red light, and the phosphorescence layer 140b may be formed as an emission layer emitting blue light.

The fluorescence layer 140a and the phosphorescence layer 140b serve as an emission layer (EML) 140. Thereby, in the process of driving the organic electroluminescent device, the emission layer 140 may emit white light.

Meanwhile, the fluorescence layer 140a neighboring the first electrode 110 or the anode, preferably, has a thickness of 50 to 200 Å, and the phosphorescence layer 140b, preferably, has a thickness of 50 to 300 Å. Thereby, in the process of driving the organic electroluminescent device, a width of an emission region formed within the emission layer 140 may be increased.

A hole blocking layer (HBL) 150 may be formed on the phosphorescence layer 140b. The hole blocking layer 150 serves to suppress excitons generated from the phosphorescence layer 140b from diffusing in the process of driving the organic electroluminescent device. The hole blocking layer 150 may be formed of Balq, BCP, CF-X, TAZ, or spiro-TAZ.

Subsequently, an electron transport layer (ETL) 160a s an electric charge transport layer and electron injection layer (EIL) 170 as an electric charge injection layer may be sequentially formed on the hole blocking layer 150. Anyone of the electron transport layer 160 and the electron injection layer 170 may not be formed. The electron transport layer 160 is a layer for facilitating to transport electrons to the emission layer 140, and may be formed, for example, either of a polymer material such as PBD, TAZ, or spiro-PBD, or of a low molecular weight material such as Alq3, BAlq or SAlq. The electron injection layer 170 is a layer for facilitating to inject electrons into the emission layer 140, and may be formed, for example, of Alq3, LiF, a Ga complex, or PBD.

Next, a second electrode 180 may be formed on the electron injection layer 170. The second electrode 180 is formed of Mg, Ca, Al, Ag, Ba, or their alloys. Further, the second electrode 180 is formed to be thin enough to penetrate light in the case of a transparent electrode, and to be thick in the case of a relative electrode. Thereby, the second electrode 180 may be formed as a cathode. Any of of the first and second electrodes 110 and 180 is formed of the transparent electrode that light can penetrate.

Alternatively, the first electrode 110 may be formed as a cathode, and the second electrode 180 may be formed as an anode. In this case, the organic electroluminescent device may be formed to have a structure where the first electrode 110, the electron injection layer 170, the electron transport layer 160, the hole blocking layer 150, the phosphorescence layer 140b, the fluorescence layer 140a, the hole transport layer 130, the hole injection layer 120, and the second electrode 180 are sequentially stacked on the substrate 100.

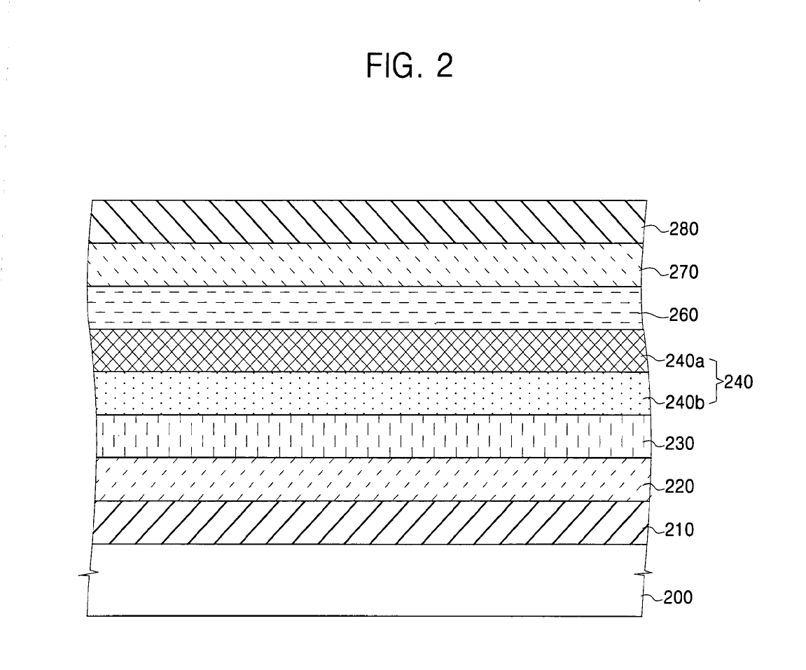

FIG. 2 is a cross-sectional view for illustrating an organic electroluminescent device and method of fabricating the same in accordance with a second embodiment of the present invention. The organic electroluminescent device according to the second embodiment has an emission layer that is different from that according to the first embodiment.

Referring to FIG. 2, a first electrode 210 is formed on a substrate 200. The first electrode 210 may be formed of a transparent electrode or a reflective electrode. When the first electrode 210 is a transparent electrode, it is formed of ITO or IZO. When the first electrode 210 is a reflective electrode, it is formed of Ag, Al, Ni, Pt, Pd, or their alloys. Thereby, the first electrode 210 may be formed as an anode.

A hole injection layer (HIL) 220 as an electric charge injection layer, and a hole transport layer (HTL) 230 as an electric charge transport layer may be sequentially formed on the first electrode 210. Alternatively, any one of the hole injection layer 220 and the hole transport layer 230 may not be formed. The hole injection layer 220 is a layer for injecting electric charges into an emission layer which will be formed in the subsequent process, which may be formed of a low molecular weight material such as CuPc, TNATA, TCTA, TDAPB, or TDATA, or a polymer material such as PANI or PEDOT. Further, the hole transport layer 230 is a layer for transporting electric charges to an emission layer which will be formed in the subsequent process, which may be formed of a low molecular weight material such as α-NPB, TPD, s-TAD, or MTADATA, or a polymer material such as PVK.

A phosphorescence layer 240b is formed on the hole transport layer 230. The phosphorescence layer 240b is preferably formed of an emission layer that emits light belonging to an orange-red range. The orange-red light may have a wavelength of 560 to 620 nm. In this case, the phosphorescence layer 240b may contain one selected from a group consisting of arylamines, carbaxoles, and spiros, which are host materials. The host material may include on selected from a group consisting of 4,4-N,N dicarbazole-byphenyl (CBP), (CBP) derivative, N,N-dicarbazolyl-3,5-benzene (mCP) and mCP derivative. In addition, the phosphorescence layer 240b may include a phosphorescent organic metal complex having one central metal selected from a group consisting of Ir, Pt, Tb, and Eu, as a dopant material. The dopant material may contain one, as a phosphorescent organic metal complex, selected from a group consisting of PQIr(acac), PQ₂Ir (acac), PIQIr(acac), PtOEP, Btp₂Ir, and Ir(piq)₃.

A fluorescence layer 240a is formed on the phosphorescence layer 240b. The fluorescence layer 240a is preferably formed of an emission layer that emits light belonging to a blue range. The blue light may have a wavelength of 440 to 500 nm. In this case, the fluorescence layer 240a may be formed to contain one selected from a group consisting of DSA, DSA derivative, DSB, DSB derivative, DPVBi, DPVBi derivative, spiro-DPVBi, spiro-6P, TBSA, BFA-1T and TPBI. Furthermore, the fluorescence layer 240a may be formed to further contain one selected from a group consisting of styrylamines, phenylenes, and DSBPs (distyrylbiphenyls), as a dopant material.

Both the phosphorescence layer 240b and the fluorescence layer 240a constitute the emission layer 240. Thereby, in the process of driving the organic electroluminescent device, the emission layer 240 may emit white light.

Most preferably, the phosphorescence layer 240b is formed as an emission layer emitting orange-red light, and the fluorescence layer 240a is formed as an emission layer emitting blue light. Alternatively, the phosphorescence layer 240b may be formed as an emission layer emitting blue light, and the fluorescence layer 240a may be formed as an emission layer emitting orange-red light.

Meanwhile, the phosphorescence layer 240b neighboring the first electrode 210 or the anode, preferably, has a thickness of 50 to 200 Å, and the fluorescence layer 240a, preferably, has a thickness of 50 to 300 Å. Thereby, in the process of driving the organic electroluminescent device, an emission region formed within the emission layer 240 may be increased in width.

The fluorescence layer 240a may serve as a hole blocking layer with respect to the phosphorescence layer 240b. Alternatively, the hole blocking layer (not shown) may be separately formed on the fluorescence layer 240a. The hole blocking layer serves to suppress excitons generated from the phosphorescence layer 240b from diffusing in the process of driving the organic electroluminescent device. When the hole blocking layer is separately formed, it may be formed of BAlq, BCP, CF-X, TAZ, or spiro-TAZ.

Subsequently, an electron transport layer 260 as an electric charge transport layer and an electron injection layer 270 may be formed on the hole blocking layer or on the fluorescence layer 240a when the hole blocking layer is not formed. Alternatively, one or both of the electron transport layer 260 and the electron injection layer 270 may be omitted. The electron transport layer 260 is a layer for transporting electrons to the emission layer 240, and may be formed, for example, either of a polymer material such as PBD, TAZ, or spiro-PBD, or of a low molecular weight material such as Alq3, Balq, or SAlq. The electron injection layer 270 is a layer for injecting electrons into the emission layer 240, and may be formed, for example, or Alq3, LiF, Ga complex, or PBD.

Next, a second electrode 280 may be formed on the electron injection layer 270. The second electrode 280 is formed on Mg, Ca, Al, Ag, Ba, or their alloys. Further, the second electrode 280 is formed to be thin enough for light to penetrate when being a transparent electrode, and to be thick when being a reflective electrode. Thereby, the second electrode 280 may be formed as a cathode. However, any one of the first and second electrodes 210 and 280 is formed of a transparent electrode light can penetrate.

Alternatively, the first electrode 210 may be formed as a cathode, and the second electrode 280 may be formed as an anode. In this case, the organic electroluminescent device may be formed to have a structure where the first electrode 210, the electron injection layer 270, the electron transport layer 260, the fluorescence layer 240a, the phosphorescence layer 240b, the hole transport layer 230, the hole injection layer 220 and the second electrode 280 are sequentially stacked on the substrate 200.

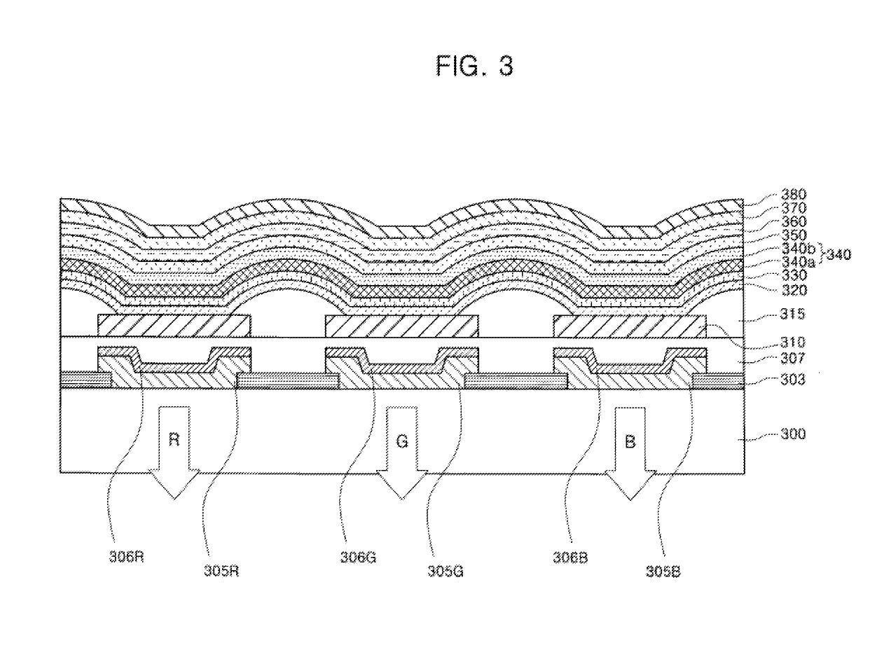

FIG. 3 is a cross-sectional view showing a full-color organic electroluminescent display and method of fabricating the same in accordance with a third embodiment of the present invention.

Referring to FIG. 3, there is provided a substrate 300. The substrate 300 may be provided with a transparent substrate that light can penetrate. Black matrixes 303 that are spaced apart from each other are formed on the substrate 300. The black matrixes 303 serve to absorb external light and scattered light. A red color filter layer 305R, a green color filter layer 305G and a blue color filter layer 305B are each formed between the black matrixes 303.

Each color filter layer may contain a pigment and a polymeric binder. The red color filter layer 305R, the green color filter layer 305G, and the blue color filter layer 305B have characteristics that selectively allow penetration of light emitted from an emission layer, which will be formed in the subsequent process, more specifically, a wavelength in the red range, a wavelength in the green range, and a wavelength in the blue range, respectively. To this end, the red, green, and blue color filter layers 305R, 305G, and 305B contain pigments having different properties from each other.

A red color conversion layer 306R, a green color conversion layer 306G, and a blue color conversion layer 306B are formed on the red, green, and blue color filter layers 305R, 305G, and 305B, respectively. Alternatively, these color conversion layers may not be formed. The color conversion layers may contain a fluorescent material and a polymer binder. The fluorescent material is excited by light incident from the emission layer and then transitioned to a ground state, thereby emitting light having a wavelength longer than the incident light. Thus, the red, green, and blue color conversion layers 306R, 306G, and 306B contain fluorescent materials having different properties from each other.

An overcoating layer 307 is formed on the substrate on which the red, green and blue color conversion layers 306R, 306G and 306B have been formed. The overcoating layer 307 is formed of a transparent layer, and serves not only to protect the red, green and blue color filter layers 305R, 305G, and 305B and the red, green and blue color conversion layers 306R, 306G, and 306B from a physical damage, but also to release a step generated by formation of the red, green and blue color filter layers 305R, 305G, and 305B and the red, green and blue color conversion layers 306R, 306G, and 306B. First electrodes 310 are formed on the overcoating layer 307, so as to correspond to the red, green and blue color filter layers 305R, 305G and 305B, respectively. The first electrodes 310 may be formed of transparent electrodes.

A pixel defining layer 315 having an opening that partially exposes a surface of each of the first electrodes 310 may be formed on the substrate 300 on which the first electrodes 310 have been formed. The pixel defining layer 315 is formed, for example, of an acryl-based organic layer. Next, a fluorescence layer 340a and a phosphorescence layer 340b are sequentially formed on the entire surface of the substrate including the exposed first electrodes 310. The fluorescence layer 340a and the phosphorescence layer 340b constitute an emission layer 340. A hole injection layer 320 and/or a hole transport layer 330 may be further formed on the exposed first electrodes 310 before the fluorescence layer 340a is formed. A hole blocking layer 350 may be formed on the phosphorescence layer 340b. Subsequently, an electron transport layer 360 and/or an electron injection layer 370 may be formed on the hole blocking layer 350. Next, a second electrode 380 running across the first electrodes 310 is formed on the electron injection layer 370. A detailed description about the first electrodes 310, the hole injection layer 320, the hole transport layer 330, the fluorescence layer 340a, the phosphorescence layer 340b, the hole blocking layer 350, the electron transport layer 360, and the electron injection layer 370 will make reference to the first embodiment.

Alternatively, the emission layer 340 may be formed as in the organic electroluminescent device according to the foregoing second embodiment.

When the organic electroluminescent display is driven, the emission layer 340 emits white light. The white light emitted from the emission layer 340 is extracted outside through the first electrodes 310 as transparent electrodes and the substrate 300 as a transparent substrate. At this time, the red, green and blue color filter layers 305R, 305G and 305B are located on a path through which the light extracted outside from the emission layer 340 passes. Therefore, while the organic electroluminescent display is driven, the white light emitted from the emission layer 340 passes through each of the red, green and blue color filter layers 305R, 305G, and 305B to be extracted outside, so that it is possible to realize full colors of red (R), green (G), and blue (B).

While the embodiments have described the organic electroluminescent display where the color filter layers are located under the emission layer 340, i.e., a bottom emission organic electroluminescent display by way of an example, it may be understood to those skilled in the art that the present invention may be applied to a top emission organic electroluminescent display or a double-sided emission organic electroluminescent display.

Hereinafter, examples are presented in order to help illustrate the present invention. However, the following examples are only intended to help illustrate, and not to restrict, the present invention.

### FABRICATION EXAMPLE

Fabrication of White Light Emitting Organic Electroluminescent Device

A first electrode having an area of 2 mm×2 mm was formed of ITO on a substrate. The substrate was subjected to ultrasonic cleaning and UV-03 cleaning. A hole injection layer was formed by vacuum depositing TDATA (4,4′4″-tris(N,N-diphenyl-anino)triphenylamine) to a thickness of 600 Å on the first electrode cleaned with UV-03. A hole transport layer was formed by vacuum depositing α-NPB (N,N′-bis(naphthalene-1-yl)-N,N′bis(phenyl)benzidine; HOMO (highest occupied molecular orbital) 5.4 eV, LUMO (lowest unoccupied molecular orbital) 1.9 eV) to a thickness of 300 Å on the hole injection layer. A fluorescence layer emitting blue light was formed by doping 4,4′-bis[2,2′-di(4dialkylaminophenyl)vinyl]-1,1′-biphenyl into DPVBi at 1.5 wt % and vacuum depositing the doped material to a thickness of 60 Å on the hole transport layer. A phosphorescence layer emitting orange-red light was formed by doping PQ₂Ir(acac) (iridium(III) bis(2-phenylquinolylN,C2′)acetylacetonate) into CBP (available from UDC company) at 7 wt %, and vacuum depositing the doped material to a thickness of 250 Å on the fluorescence layer. A hole blocking layer, an electron transport layer and an electron injection layer were sequentially formed on the phosphorescence layer by vacuum depositing BAlq to a thickness of 50 Å, by vacuum depositing Alq3 to a thickness of 300 Å, and by vacuum depositing LiF to a thickness of 20 Å, respectively. A second electrode was formed by vacuum depositing aluminum (Al) on the electron injection layer to a thickness of 3000 Å.

### COMPARATIVE EXAMPLE

Fabrication of White Light Emitting Organic Electroluminescent Device

A first electrode having an area of 2 mm×2 mm was formed of ITO on a substrate. The substrate was subjected to ultrasonic cleaning and UV-03 cleaning. A hole injection layer was formed by vacuum depositing TDATA to a thickness of 600 Å on the first electrode cleaned with UV-03. A hole transport layer was formed by vacuum depositing α-NPB to a thickness of 300 Å on the hole injection layer. A first fluorescence layer emitting blue light was formed by doping 4,4′-bis[2,2′-di(4-dialkylaminophenyl)vinyl]-1,1′-biphenyl into DPVBi at 1.5 wt % and vacuum depositing the doped material to a thickness of 60 Å on the hole transport layer. A second fluorescence layer emitting orange-red light was formed by doping IDEMITSUP1 (available from Idemitsu Company) into DPVBi at 3 wt % and vacuum depositing the doped material to a thickness of 250 Å on the first fluorescence layer. A hole blocking layer, an electron transport layer and electron injection layer were sequentially formed on the second fluorescence layer by vacuum depositing BAlq to a thickness of 50 Å, by vacuum depositing Alq3 to a thickness of 300 Å, and by vacuum depositing LiF to a thickness of 20 Å, respectively. A second electrode was formed by vacuum depositing aluminum (Al) to a thickness of 3000 Å on the electron injection layer.

The following Table 1 shows luminance yield of the white light emitting organic electroluminescent devices fabricated according to the Fabrication Example and the Comparative Example.

TABLE 1

| | Reference Voltage | Luminance |
|---|---|---|
| | (V, @ 500 cd/m²) | yield (cd/A) |
| Fabrication Example | 7.5 | 12.5 |
| Comparative Example | 6.0 | 9.4 |

Referring to Table 1, it may be seen that the luminance yield of the organic electroluminescent device according to Fabrication Example is improved compared to that of the organic electroluminescent device according to Comparative Example.

According to exemplary embodiments of the present invention as set forth above, it is possible to obtain a white light emitting organic electroluminescent device having an improved luminance yield by including an emission layer having a fluorescence layer and a phosphorescence layer.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. An organic electroluminescent device emitting white light, comprising:
a first electrode;
a second electrode; and
an emission layer interposed between the first and second electrodes and comprising a fluorescence layer and a phosphorescence layer.

2. The organic electroluminescent device as claimed in claim 1, wherein the fluorescence layer emits light in a blue range.

3. The organic electroluminescent device as claimed in claim 2, wherein the fluorescence layer comprises one selected from the group consisting of distyrylarylene (DSA), a DSA derivative, distyrylbenzene (DSB), a DSB derivative, 4,4′-bis(2,2′-diphenyl vinyl)-1,1′-biphenyl (DPVBi), a DPVBi derivative, spiro-DPVBi, spiro-sexyphenyl (spiro-6P), 9,10-bis[(2″7″-t-butyl)-9′,9″-spirobifluorenyl]anthracene (TBSA), 2,5-bis{4-[bis-(9,9-dimethyl-2-fluorenyl)amino]phenyl}thiophene (BFA-1T), and N-arylbenzimidazoles (TPBI).

4. The organic electroluminescent device as claimed in claim 3, wherein the fluorescence layer further comprises a dopant material selected from the group consisting of a styrylamine, a phenylene, and a distyrylbiphenyl.

5. The organic electroluminescent device as claimed in claim 1, wherein the phosphorescence layer emits light in an orange-red range.

6. The organic electroluminescent device as claimed in claim 5, wherein the phosphorescence layer comprises a host material selected from the group consisting of an arylamine, a carbazole, and a spiro.

7. The organic electroluminescent device as claimed in claim 6, wherein the host material comprises one selected from the group consisting of 4,4-N,N dicarbazole-biphenyl (CBP), a CBP derivative, N,N-dicarbazolyl-3,5-benzene (mCP), and an mCP derivative.

8. The organic electroluminescent device as claimed in claim 5, wherein the phosphorescence layer comprises a phosphorescent organic metal complex comprising a central metal selected from the group consisting of Ir, Pt, Tb, and Eu, as a dopant material.

9. The organic electroluminescent device as claimed in claim 8, wherein the dopant material comprises a phosphorescent organic metal complex selected from the group consisting of PQIr (tris(1-phenylquinoline)iridium), PQIr(acac) (bis(1-phenylquinoline)acetylacetonate iridium), PQ₂Ir(acac) (iridium III) bis(2-phenylquinolyl-N,C2′)acetylacetonate), PIQIr(acac) (bis(1-phenylisoquinoline)acetylacetonate iridium), PtOEP(octaethylporphyrin platinum), Btp₂Ir bis(2-(2′-benzo[4,5-a]thienyl)pyridinato-N,C2′)iridium(acetylacetonate), and Ir(piq)₃(tris[1-phenylisoquinolinato-C2,N]iridium(III)).

10. The organic electroluminescent device as claimed in claim 1, wherein:
the fluorescence layer emits light in a blue range; and
the phosphorescence layer emits an orange-red range.

11. The organic electroluminescent device as claimed in claim 11, further comprising at least one selected from the group consisting of a hole injection layer, a hole transport layer, an electron injection layer, an electron transport layer, and a hole blocking layer.

12. The organic electroluminescent device as claimed in claim 1, wherein:
the first electrode is an anode;
the fluorescence layer is disposed on the first electrode; and
the phosphorescence layer is disposed on the fluorescence layer.

13. The organic electroluminescent device as claimed in claim 12, further comprising a hole blocking layer disposed on the phosphorescence layer.

14. The organic electroluminescent device as claimed in claim 12, wherein the fluorescence layer has a thickness in a range of 50 to 200 Å.

15. The organic electroluminescent device as claimed in claim 12, wherein the phosphorescence layer has a thickness in a range of 50 to 300 Å.

16. The organic electroluminescent device as claimed in claim 1, wherein:
the first electrode is an anode;
the phosphorescence layer is disposed on the first electrode; and
the fluorescence layer is disposed on the phosphorescence layer.

17. The organic electroluminescent device as claimed in claim 16, wherein the phosphorescence layer has a thickness in a range of 50 to 200 Å.

18. The organic electroluminescent device as claimed in claim 16, wherein the fluorescence layer has a thickness in a range of 50 to 300 Å.

19. An organic electroluminescent display comprising:
first and second electrodes, at least one of the first and second electrodes being a transparent electrode;
an emission layer interposed between the first and second electrodes and configured to emit white light, the emission layer comprising a fluorescence layer and a phosphorescence layer; and
a color filter layer disposed to receive the light emitted from the emission layer.

20. The organic electroluminescent display as claimed in claim 19, wherein the fluorescence layer emits light in a blue range.

21. The organic electroluminescent display as claimed in claim 20, wherein the fluorescence layer comprises:
one selected from the group consisting of distyrylarylene (DSA), a DSA derivative, distyrylbenzene (DSB), a DSB derivative, 4,4′-bis(2,2′-diphenyl vinyl)-1,1′-biphenyl (DPVBi), a DPVBi derivative, spiro-DPVBi, spiro-sexyphenyl (spiro-6P), 9,10-bis[(2″7″-t-butyl)-9′,9″-spirobifluorenyl]anthracene (TBSA), 2,5-bis{4-[bis-(9,9-dimethyl-2-fluorenyl)amino]phenyl}thiophene (BFA-1T), and N-arylbenzimidazoles (TPBI); and
a dopant material selected from the group consisting of a styrylamine, a phenylene, and a distyrylbiphenyl.

22. The organic electroluminescent display as claimed in claim 19, wherein the phosphorescence layer emits light in an orange-red range.

23. The organic electroluminescent display as claimed in claim 22, wherein the phosphorescence layer comprises:
a host material selected from the group consisting of 4,4-N,N dicarbazole-biphenyl (CBP), a CBP derivative, N,N-dicarbazolyl-3,5-benzene (mCP), and an mCP derivative; and
a dopant material selected from the group consisting of PQIr (tris(1-phenylquinoline)iridium), PQIr(acac) (bis(1-phenylquinoline)acetylacetonate iridium), PQ₂Ir(acac) (iridium(III) bis(2-phenylquinolyl-N,C2′)acetylacetonate), PIQIr(acac) (bis(1-phenylisoquinoline)acetylacetonate iridium), PtOEP(octaethylporphyrin platinum), Btp₂Ir bis(2-(2′-benzo[4,5-a]thienyl)pyridinato-N,C2′)iridium(acetylacetonate), and Ir(piq)₃(tris[1-phenylisoquinolinato-C2,N]iridium(III)).

24. The organic electroluminescent display as claimed in claim 19, wherein:
the fluorescence layer emits light in a blue range; and
the phosphorescence layer emits light in an orange-red range,

25. The organic electroluminescent display as claimed in claim 19, further comprising at least one selected from the group consisting of a hole injection layer, a hole transport layer, an electron injection layer, an electron transport layer, and a hole blocking layer.

26. The organic electroluminescent display as claimed in claim 19, wherein:
the first electrode is an anode;
the fluorescence layer is disposed on the first electrode; and
the phosphorescence layer is disposed on the fluorescence layer.

27. The organic electroluminescent display as claimed in claim 26, further comprising a hole blocking layer disposed on the phosphorescence layer.

28. The organic electroluminescent display as claimed in claim 19, wherein:
the first electrode is an anode;
the phosphorescence layer is disposed on the first electrode; and
the fluorescence layer is disposed on the phosphorescence layer.
